(19) United States
(12) Patent Application Publication
(10) Pub. No.: US 2016/0106005 A1
(43) Pub. Date: Apr. 14, 2016

(54) CARBON NANOTUBES AS A THERMAL INTERFACE MATERIAL

(71) Applicant: NTHERMA CORPORATION, Milpitas, CA (US)

(72) Inventors: Cattien Ngyuen, San Jose, CA (US); Be Van Vo, Santa Clara, CA (US); Anthony Vu, San Jose, CA (US)

(21) Appl. No.: 14/881,158

(22) Filed: Oct. 13, 2015

Related U.S. Application Data
(60) Provisional application No. 62/063,253, filed on Oct. 13, 2014.

(51) Int. Cl. H05K 7/20; B23P 15/26

(52) U.S. Cl. CPC H05K 7/20509; B23P 15/26

(57) ABSTRACT

Provided herein is an apparatus including a thermal interface material incorporating carbon nanotubes attached to a depression on a heat sink, where the thickness of the thermal interface material is greater than the depth of the depression on the heat sink and methods of making thereof. The thermal interface material may be further attached to a functional device(s) and transfers heat from the device(s) to the heat sink.

This application claims priority under 35 U.S.C. §119 (e) from U.S. Provisional Application Ser. No. 62/063,253 filed Oct. 13, 2014, respectively, which is hereby incorporated by reference in its entirety.

### FIELD

Provided herein is an apparatus including a thermal interface material incorporating carbon nanotubes attached to a depression on a heat sink, where the thickness of the thermal interface material is greater than the depth of the depression on the heat sink and methods of making thereof. The thermal interface material may be further attached to a functional device(s) and transfers heat from the device(s) to the heat sink.

### BACKGROUND

Thermal interface materials may be used for example, in microelectronic devices, light emitting diode (LED) devices, power electronics and batteries. The complexity of modern devices requires multiple-levels of integration and heat dissipation is an increasingly critical issue as integrated circuits reach increasingly infinitesimal size. Heat sinks, which function as heat spreaders, are use to transfer heat from the functional devices to the periphery of the packaging area. The poor heat conductivity of air requires thermal interface materials in conductive contact with functional devices and a heat sink, to efficiently transfer heat to the heat sink from the functional devices.

Although, inherent thermal conductivity is of critical importance, other parameters need to be optimized in design of a thermal interface material. A thermal interface material should be mechanically flexible to maximize the contact area between the functional devices and the thermal interface material and the thermal interface material and the heat sink. Ideally, the thermal interface material conforms to the surface morphology of both the functional devices and heat sink.

Mechanical strength and resistance to physical cracking during temperature cycling are also advantageous properties of a thermal interface material. Thermal interface materials of low thermal expansion coefficient are highly desirable to avoid significant physical deformation during temperature cycling. Excessive physical deformation of the thermal interface material can cause damage to the functional devices in combination. Finally, thermal stability at the temperature regime of the functional devices is essential to avoid thermal-chemical degradation of the material and properties of the thermal interface material.

Carbon nanotubes are a relatively new form of carbon material with exceptional physical properties, such as thermal stability, high thermal conductivity, mechanical strength, low thermal expansion coefficient and large surface area, which may be advantageously, included in thermal interface materials.

Thermal interface materials typically need to be integrated with a heat sink to form an apparatus for efficiently transferring heat from functional device(s) to the heat sink. Accordingly, what is needed are novel methods and apparatuses which integrate thermal interface materials which include carbon nanotubes with heat sinks where at least a portion of the thermal interface materials is in conductive contact with a functional device(s) to transfer heat from the device to the heat sink s.

### SUMMARY

The present invention satisfies these and other need by providing, in one aspect, an apparatus including a thermal interface material incorporating carbon nanotubes attached to a depression on a heat sink, where the thickness of the thermal interface material is greater than the depth of the depression on the heat sink.

In another aspect, a method of making the above apparatus is provided. The thermal interface material is attached to the heat sink depression and a device is attached to the thermal interface material.

### BRIEF DESCRIPTION OF THE FIGURES

FIG. 1 illustrates an exemplary flowchart for fabricating carbon nanotubes on a metal substrate including one or more cavities, where the cavities are introduced in the metal substrate prior to catalyst deposition;

FIG. 2 illustrates an exemplary flowchart for fabricating carbon nanotubes on a metal substrate including one or more cavities, where the cavities are introduced in the metal substrate after catalyst deposition;

FIG. 3 illustrates an exemplary flowchart for fabricating carbon nanotubes on a metal substrate including one or more cavities, where catalyst deposition is not required;

FIG. 4 illustrates a metal substrate with a thickness t;

FIG. 5 illustrates a metal substrate with one or more cavities with a diameter d and a cavity-to-cavity separation D;

FIG. 6 illustrates deposition of carbon nanotubes on a metal substrate with one or more cavities, where the carbon nanotubes are vertically aligned with respect to the metal substrate surface and are deposited on the portion of the metal substrate without cavities.

FIG. 7 illustrates a cross-section of vertically aligned carbon nanotubes deposited on both sides of a metal substrate including one or more cavities, where the carbon nanotubes have lower density in areas around the cavity edges.

FIG. 8 illustrates an embodiment of an apparatus which includes a device, a heat sink and a thermal interface material. In the depicted embodiment, the thermal interface material includes vertically aligned carbon nanotubes disposed on both side of a metal substrate including cavities. The thermal interface material is in conductive contact with the device and the heat sink and dissipates heat from the device to the heat sink;

FIG. 9 illustrates another embodiment of an apparatus which includes a device, a heat sink and a thermal interface material. The thermal interface material includes vertically aligned carbon nanotubes disposed on both side of a metal substrate including cavities. The carbon nanotube density is lower at the edges of the cavities. The thermal interface material is in conductive contact with the device and the heat sink and dissipates heat from the device to the heat sink;

FIG. 10 illustrate an exemplary flowchart of a process for fabricating an apparatus integrating thermal interface material including carbon nanotubes attached to a heat sink;

FIG. 11 illustrates a heat sink in top-down view 1100 and cross-section view 1150 of a depression 1110 and 1160 in the heat sink;

FIG. 12 illustrates a heat sink in top-down view 1200 and cross-section view 1240, where an adhesive 1220 and 1260 is applied at the edges of the depression 1210 and 1250 in the heat sink.

FIG. 13 illustrates attachment of thermal interface material 1300 to the depression 1360 of heat sink 1350 with adhesive 1370.

FIG. 14 illustrates integration of the thermal interface material attached to heat sink apparatus where the tips of the carbon nanotubes make contact with the functional device 1410;

FIG. 15 illustrates a thermal interface material attached to heat sink in conjunction with a functional device 1510 using additional mechanical clamps 1520A and 1520B to enhance the contact between the tips of the carbon nanotube with the functional device.

### DETAILED DESCRIPTION

### Definitions

Unless defined otherwise, all technical and scientific terms used herein have the same meaning as is commonly understood by one of ordinary skill in the art to which this invention belongs. In the event that there is a plurality of definitions for a term herein, those in this section prevail unless stated otherwise.

As used herein “carbon nanotubes” refer to allotropes of carbon with a cylindrical structure. Carbon nanotubes may have defects such as inclusion of C5 and/or C7 ring structures, such that the carbon nanotube is not straight; and may have contain coiled structures; and may contain randomly distributed defected sites in the C—C bonding arrangement. Carbon nanotubes may contain one or more concentric cylindrical layers.

As used herein “catalysts” or “metal catalysts” refer to a metal or a combination of metals such as Fe, Ni, Co, Cu, Au, etc. that are used in the breakdown of hydrocarbon gases and aid in the formation of carbon nanotubes by chemical vapor deposition process.

As used herein “chemical vapor deposition” refers to plasma-enhanced chemical vapor deposition or thermal chemical vapor deposition.

As used herein “plasma-enhanced chemical vapor deposition” refers to the use of plasma (e.g., glow discharge) to transform a hydrocarbon gas mixture into excited species which deposit carbon nanotubes on a surface.

As used herein “thermal chemical vapor deposition” refers to the thermal decomposition of hydrocarbon vapor in the presence of a catalyst which may be used to deposit carbon nanotubes on a surface.

As used herein “physical vapor deposition” refers to vacuum deposition methods used to deposit thin films by condensation of a vaporized of desired film material onto film materials and includes techniques such as cathodic arc deposition, electron beam deposition, evaporative deposition, pulsed laser deposition and sputter deposition.

As used herein “thermal interface material” refers to a material that conducts heat from functional device(s) to a heat sink.

As used herein “functional device(s)” refers to any device(s) which generate heat in the course of operation. Examples of functional devices include microelectronics computer processing units, microelectronics memory devices, light emitting diodes, a battery, a battery systems, power supplies, etc.

As used herein “heat sink” refers to a block of metal, with elevated surface area, which may be generated by complex structure, which can spread heat and dissipate heat by convection.

An apparatus including a thermal interface material incorporating carbon nanotubes attached to a depression on the surface of a heat sink is provided herein. A key feature is thermal interface material where attached to a heat sink. The apparatus provided thermal interface material in conductive contact with the functional device(s) and the heat sink which transfers heat from the device to the heat sink.

Carbon nanotubes are a relatively new material with exceptional physical properties, such as superior current carrying capacity, high thermal conductivity, good mechanical strength, and large surface area, which are advantageous in a number of applications. Carbon nanotubes possess exceptional thermal conductivity with a value as high as 3000 W/mK which is only lower than the thermal conductivity of diamond. Carbon nanotubes are mechanically strong and thermally stable above 400° C. under atmospheric conditions. Carbon nanotubes have reversible mechanical flexibility particularly when vertically aligned. Accordingly, carbon nanotubes are able to mechanically conform to different surface morphologies because of this intrinsic flexibility. Additionally, carbon nanotubes have a low thermal expansion coefficient and retain flexibility in confined conditions under elevated temperatures.

Economically providing carbon nanotubes, in a controlled manner with practical integration and/or packaging are essential to implementing many potential carbon nanotube technologies. A compelling application of carbon nanotubes is incorporation into thermal interface materials.

In one aspect, provided herein, is a substance which includes carbon nanotubes disposed on at least one side of a metal substrate incorporating one or more cavities. In some embodiments, the one or more cavities are an aperture which breaches the substance. In some embodiments, the one or more cavities are a random shape. In other embodiments, the one or more cavities are a circle, triangle, square, pentagon, hexagon, heptagon, octagon or combinations thereof.

In some embodiments, the one or more cavities are randomly dispersed on the metal substrate. In some embodiments, the one or more cavities are regularly dispersed on the metal substrate. In still other embodiments, the one or more cavities comprise a patterned array on the metal substrate.

In some embodiments, the one or more cavities have an approximate width of between about 10 μm and about 10 cm. In other embodiments, the one or more cavities have an approximate width of between about 1 cm and about 10 cm. In still other embodiments, the one or more cavities have an approximate width of between about 1 mm and about 10 cm. In still other embodiments, the one or more cavities have an approximate width of between about 100 μm and about 10 cm. In still other embodiments, the one or more cavities have an approximate width of between about 10 μm and about 100 μm. In still other embodiments, the one or more cavities have an approximate width of between about 10 μm and about 1 mm. In still other embodiments, the one or more cavities have an approximate width of between about 10 μm and about 1 cm.

In some embodiments, the cavities in the array are separated by an approximate width of between about 10 μm and about 10 cm. In other embodiments, the cavities in the array are separated by an approximate width of between about 1 cm and about 10 cm. In still other embodiments, the cavities in the array are separated by an approximate width of between about 1 mm and about 10 cm. In still other embodiments, the cavities in the array are separated by an approximate width of between about 100 μm and about 10 cm. In still other embodiments, the cavities in the array are separated by an approximate width of between about 10 μm and about 100 μm. In still other embodiments, the cavities in the array are separated by an approximate width of between about 10 μm and about 1 mm. In still other embodiments, the cavities in the array are separated by an approximate width of between about 10 μm and about 1 cm.

It should be noted that all possible combinations of cavity separations and cavity widths which are operationally feasible are envisaged in the present invention.

In some embodiments, the carbon nanotubes are randomly aligned. In other embodiments, the carbon nanotubes are vertically aligned. In still other embodiments, the aerial density of the carbon nanotubes is between about 2 mg/cm² and about 1 mg/cm². In still other embodiments, the density of the carbon nanotubes is between about 2 mg/cm² and about 0.2 mg/cm².

In some embodiments, the density of carbon nanotubes disposed at the cavity edges is lower than the bulk density of the carbon nanotubes disposed on the metal surface. In other embodiments, the density of carbon nanotubes disposed at the cavity edges is less than about 95% of the bulk density of the carbon nanotubes disposed on the metal surface. In still other embodiments, the density of carbon nanotubes disposed at the cavity edges is less than about 90% of the bulk density of the carbon nanotubes disposed on the metal surface. In still other embodiments, the density of carbon nanotubes disposed at the cavity edges is less than about 95% of the bulk density of the carbon nanotubes disposed on the metal surface. In still other embodiments, the density of carbon nanotubes disposed at the cavity edges is less than about 70% of the bulk density of the carbon nanotubes disposed on the metal surface. In still other embodiments, the density of carbon nanotubes disposed at the cavity edges is less than about 95% of the bulk density of the carbon nanotubes disposed on the metal surface. In still other embodiments, the density of carbon nanotubes disposed at the cavity edges is less than about 50% of the bulk density of the carbon nanotubes disposed on the metal surface. In still other embodiments, the density of carbon nanotubes disposed at the cavity edges is less than about 95% of the bulk density of the carbon nanotubes disposed on the metal surface. In still other embodiments, the density of carbon nanotubes disposed at the cavity edges is less than about 10% of the bulk density of the carbon nanotubes disposed on the metal surface.

In some embodiments, the density of carbon nanotubes disposed at the cavity edges is less than about 95% of the bulk density of the carbon nanotubes disposed on the metal surface. In other embodiments, the density of carbon nanotubes disposed at the cavity edges is less than about 90% of the bulk density of the carbon nanotubes disposed on the metal surface.

In some embodiments, vertically aligned carbon nanotubes have a thermal conductivity of greater than about 50 W/mK. In other embodiments, vertically aligned carbon nanotubes have a thermal conductivity of greater than about 70 W/mK.

In some embodiments, vertically aligned carbon nanotubes comprising a patterned array have a thermal conductivity of greater than about 50 W/mK. In other embodiments, vertically aligned carbon nanotubes comprising a patterned array have a thermal conductivity of greater than about 70 W/mK. In still other embodiments, vertically aligned carbon nanotubes comprising a patterned array have a thermal conductivity of greater than about 100 W/mK.

In some embodiments, the thickness of the vertically aligned carbon nanotubes is between than about 100 μm and about 500 μm. In other embodiments, the thickness of the vertically aligned carbon nanotubes is less than about 100 μm.

In some embodiments, carbon nanotubes are disposed on two opposing sides of the metal substrate. In other embodiments, carbon nanotubes are disposed on two sides of the metal substrate. In still other embodiments, carbon nanotubes are disposed on three sides of the metal substrate. In still other embodiments, carbon nanotubes are disposed on all sides of the metal substrate.

In some embodiments, the thickness of the metal substrate is between about 0.05 μM and about 100 cm. In other embodiments, the thickness of the metal substrate is between about 0.05 mm and about 5 mm. In still other embodiments, the thickness of the metal substrate is between about 0.1 mm and about 2.5 mm. In still other embodiments, the thickness of the metal substrate is between about 0.5 mm and about 1.5 mm. In still other embodiments, the thickness of the metal substrate is between about 1 mm and about 5 mm. In still other embodiments, the thickness of the metal substrate is between about 0.05 mm and about 1 mm. In still other embodiments, the thickness of the metal substrate is between about 0.05 mm and about 0.5 mm. In still other embodiments, the thickness of the metal substrate is between about 0.5 mm and about 1 mm. In still other embodiments, the thickness of the metal substrate is between about 1 mm and about 2.5 mm. In still other embodiments, the thickness of the metal substrate is between about 2.5 mm and about 5 mm. In still other embodiments, the thickness of the metal substrate is between about 100 μM and about 5 mm. In still other embodiments, the thickness of the metal substrate is between about 10 μM and about 5 mm

In some embodiments, the thickness of the metal substrate is greater than 100 μM. In other embodiments, the thickness of the metal substrate is less than 100 μM.

In some embodiments, the metal substrate includes iron, nickel, aluminum, cobalt, copper, chromium, gold and combinations thereof. In other embodiments, the metal substrate includes iron, nickel, cobalt, copper, gold or combinations thereof.

In some embodiments, the metal substrate is an alloy of two or more of iron, nickel, cobalt, copper, chromium, aluminum, gold and combinations thereof. In other embodiments, the metal substrate is an alloy of two or more of iron, nickel, cobalt, copper, gold and combinations thereof.

In some embodiments, the metal substrate is high temperature metal alloy. In other embodiments, the metal substrate is stainless steel. In other embodiments, the metal substrate is a high temperature metal alloy on which a catalyst film is deposited for growing carbon nanotubes. In still other embodiments, the metal substrate is stainless steel on which a catalyst film is deposited for growing carbon nanotubes.

In some embodiments, the metal substrate is a metal or combination of metals which are thermally stable at greater than 500° C. In other embodiments, the metal substrate is a metal or combination of metals which are thermally stable at greater than 600° C. In still other embodiments, the metal substrate is a metal or combination of metals which are thermally stable at greater than 700° C. In some of the above embodiments, the combination of metals is stainless steel.

In some embodiments, the metal substrate has a thickness of less than about 100 μM and a surface root mean square roughness of less than about 250 nm. In other embodiments, the metal substrate has a thickness of greater than about 100 μM and a surface root mean square roughness of less than about 250 nm. In still other embodiments, the metal substrate has a thickness of less than about 100 μM and a surface root mean square roughness of less than about 250 nm and includes iron, nickel, cobalt, copper, gold or combinations thereof. In still other embodiments, the metal substrate has a thickness of greater than about 100 μM and a surface root mean square roughness of less than about 250 nm and includes iron, nickel, cobalt, copper, gold or combinations thereof. In still other embodiments, the metal substrate has a thickness of less than about 100 μM and a surface root mean square roughness of less than about 250 nm and includes a catalyst film. In still other embodiments, the metal substrate has a thickness of greater than about 100 μM and a surface root mean square roughness of less than about 250 nm and includes a catalyst film. In some of the above embodiments, the root mean square roughness is less than about 100 nm.

In some embodiments, an apparatus including a thermal interface material incorporating carbon nanotubes is attached to a depression on a heat sink, where the thickness of the thermal interface material is greater than the depth of the depression on the heat sink. In other embodiments, the thermal interface material includes substances comprising carbon nanotubes disposed on at least one side of a metal substrate including one or more cavities. In still other embodiments, the thermal interface material includes substances comprising carbon nanotubes disposed on two opposing sides of a metal substrate which includes one or more cavities.

In some embodiments, the thermal interface material is attached to the heat sink with an adhesive. In other embodiments, the adhesive is comprised of a thermal paste, thermal grease, epoxy, silver epoxy or combinations thereof. In still other embodiments, the adhesive is applied to an edge of the depression on the heat sink.

In some embodiments, the heat sink aluminum or aluminum alloy. In other embodiments, the heat sink is copper or copper alloy.

In some embodiments, the depression has a depth between about 500 μm and about 2000 μm. In other embodiments, the depression has a depth between about 50 μm and about 500 μm. In some embodiments, the depression has only one side. In some embodiments, the depression has two sides. In some embodiments, the depression has three sides. In some embodiments, the depression has more than three sides. The thermal interface material is aligned with one or more of the sides of the depression in the heat sink.

In some embodiments, a functional device(s) is attached to the thermal interface material. In other embodiments, the device is a microelectronic device, a computer, a LED device, a power electronic device, a battery, a battery system or a space system.

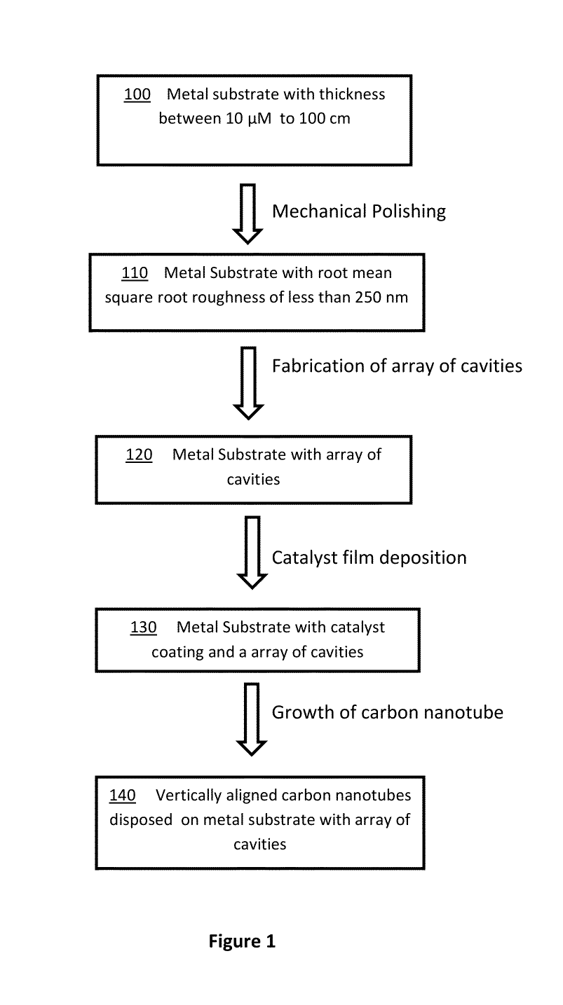

Referring now to FIG. 1, one embodiment of a method of fabricating a substance including carbon nanotubes disposed on at least one side of a metal substrate incorporating one or more cavities is illustrated. A metal substrate with a thickness between 10 μm and 100 cm is provided at 100. Mechanical polishing, which can be accomplished by a variety of methods know to the skilled artisan then provides a metal substrate with a root mean square roughness of less than about 250 nm at 110 which is used to prepare a metal substrate including an array of cavities at 120. Then, deposition of a catalyst film yields a metal substrate with a catalyst coating which includes an array of cavities at 130. Finally, carbon nanotubes are grown on the metal substrate to provide vertically aligned carbon nanotubes disposed on a metal substrate with an array of cavities at 140.

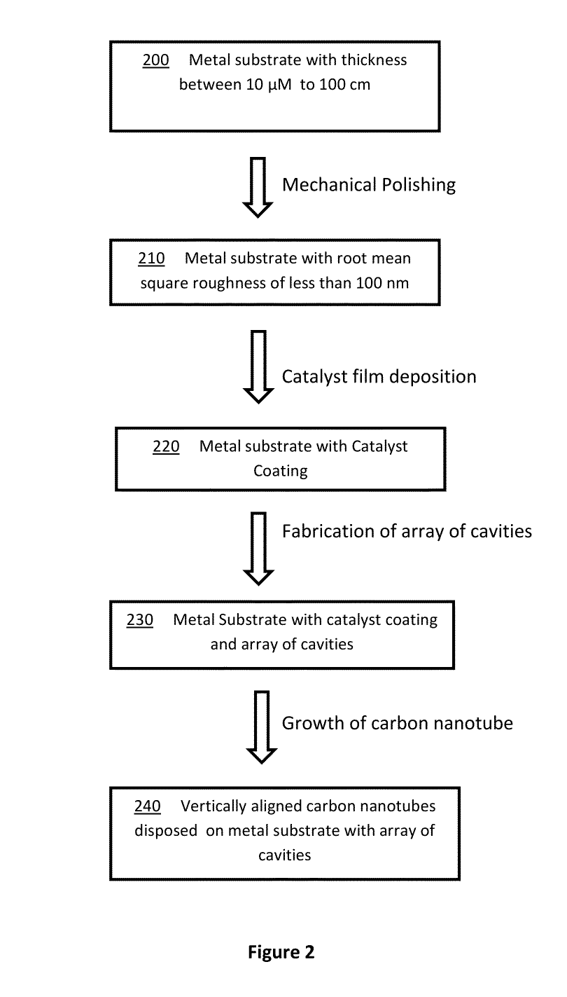

Referring now to FIG. 2, another embodiment of a method of fabricating a substance including carbon nanotubes disposed on at least one side of a metal substrate incorporating one or more cavities is illustrated. A metal substrate with a thickness between 10 μm and 100 cm is provided at 200. Mechanical polishing, which can be accomplished by a variety of methods know to the skilled artisan then provides a metal substrate with a root mean square roughness of less than about 250 nm at 210. Then deposition of a catalyst film yields a metal substrate with a catalyst coating at 220 which is used to fabricate an array of cavities at 230. Finally, carbon nanotubes are grown on the metal substrate to provide vertically aligned carbon nanotubes disposed on a metal substrate with an array of cavities at 240.

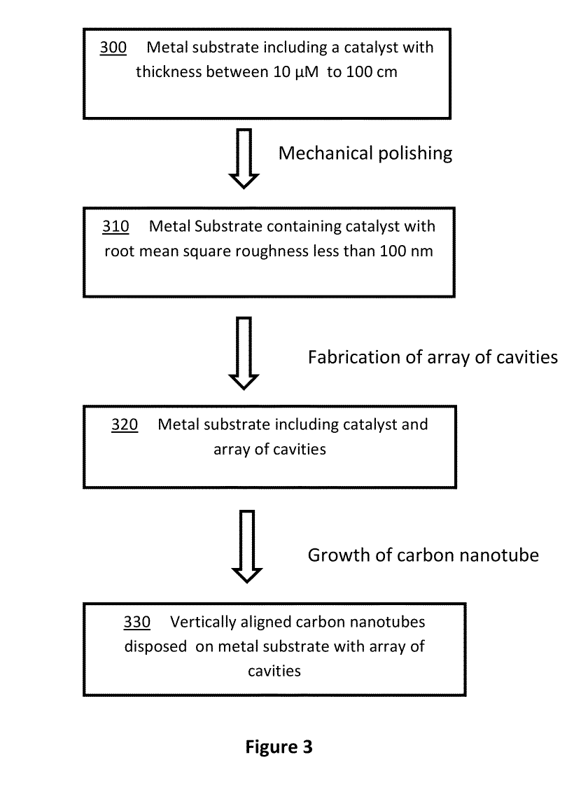

Referring now to FIG. 3, another embodiment of a method of fabricating a substance including carbon nanotubes disposed on at least one side of a metal substrate incorporating one or more cavities is illustrated. A metal substrate including a catalyst with a thickness between 10 μm and 100 cm is provided at 300. Mechanical polishing, which can be accomplished by a variety of methods know to the skilled artisan then provides a metal substrate with a root mean square roughness of less than about 250 nm at 310 which is used to fabricate an array of cavities at 320. Finally, carbon nanotubes are grown on the metal substrate to provide vertically aligned carbon nanotubes disposed on a metal substrate with an array of cavities at 330.

In some of the above embodiments, the catalyst forms a layer on the metal substrate.

In some of the above embodiments, solution deposition techniques are used to deposit the catalyst. In other embodiments, solution deposition techniques include solution dipping, spraying, ink jet and print screening.

In some of the above embodiments, physical deposition techniques are used to deposit the catalyst. In other embodiments, physical deposition techniques include ion beam sputtering, electron beam deposition, evaporative metal heating and pulsed laser deposition.

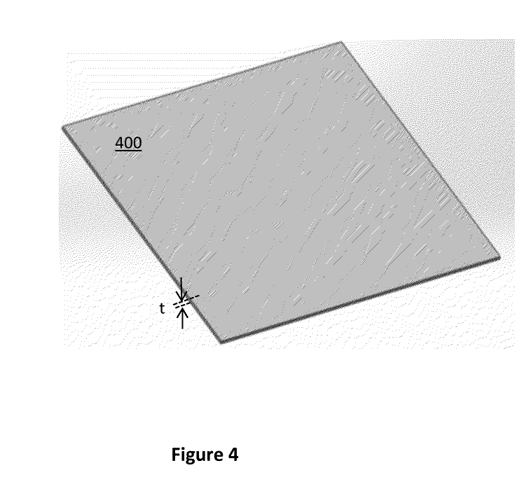

Referring now to FIG. 4, one embodiment of a metal substrate 400 with a thickness t is illustrated. The metal substrate can include any of the metals described above and can be any thickness described above.

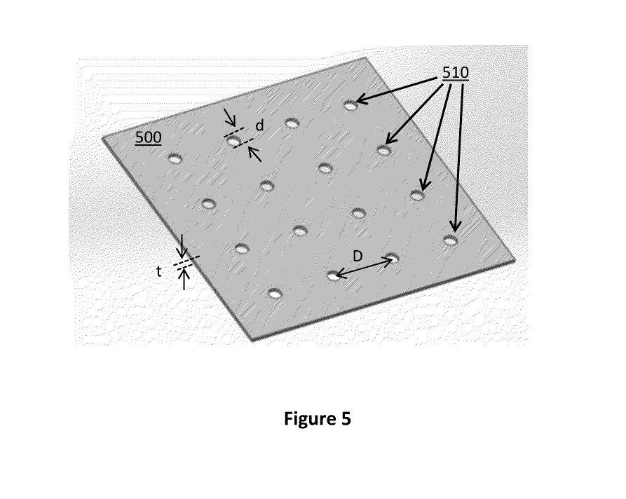

FIG. 5 illustrates one embodiment of a metal substrate 500 which includes patterned array of cavities 510. In some embodiments, the metal substrate 500 includes a 2×2 array of cavities 510. In other embodiments, the metal substrate 500 includes an array of cavities 510 greater than 2×2. In some embodiments, the cavities 510 are in a regular pattern. In other embodiments, the cavities 510 are in a random pattern. The cavities can have any geometry or combination of geometries previously described above. In some embodiments, the width of cavities d has any of the dimensions previously described above. In some embodiments, the N×N array of cavities 510 has a separation D with any of the distances described above.

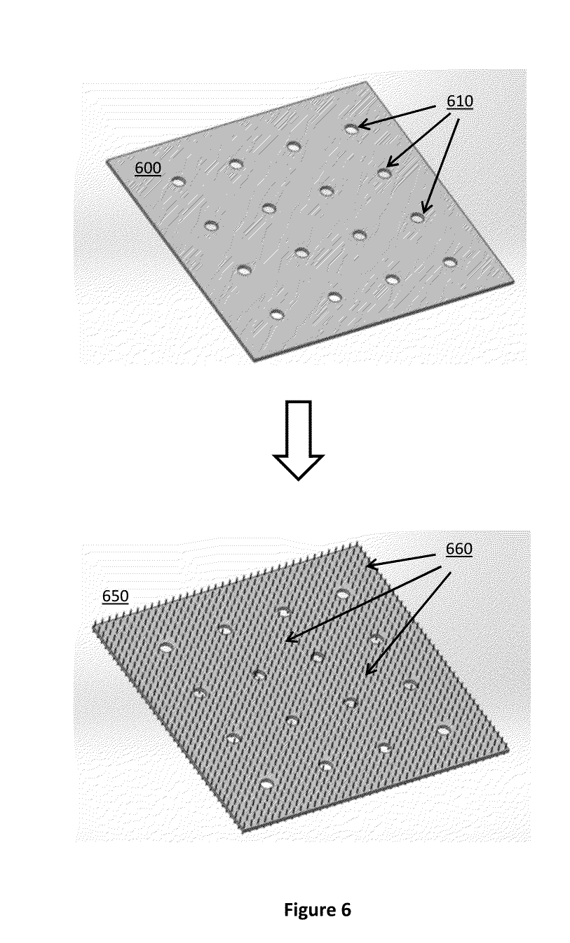

FIG. 6 illustrates one embodiment of carbon nanotube 660 deposition on a metal substrate 600 with cavities 610. The carbon nanotubes 660 are vertically aligned with respect to the metal substrate surface 650 and are deposited on the metal substrate 650 without cavities 610.

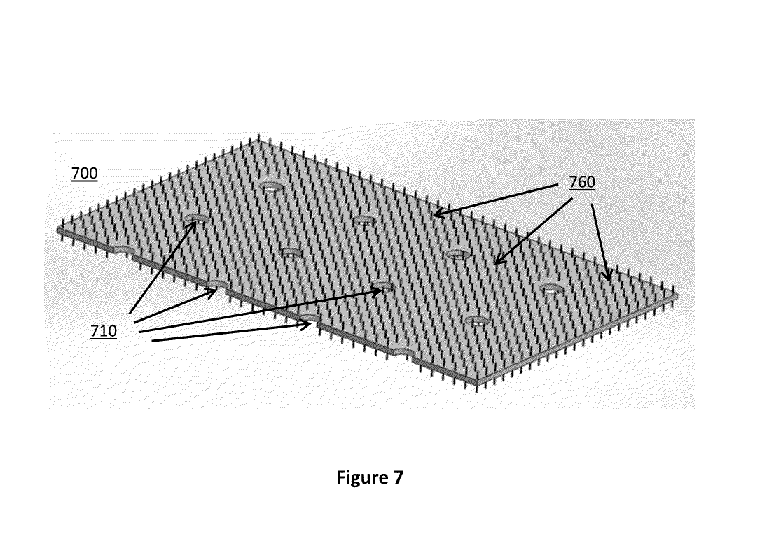

FIG. 7 illustrates one embodiment of vertically aligned carbon nanotubes 760 deposited on both sides of metal substrate 700 which includes cavities 710, where the carbon nanotubes have lower density in areas around the edges of cavity 710.

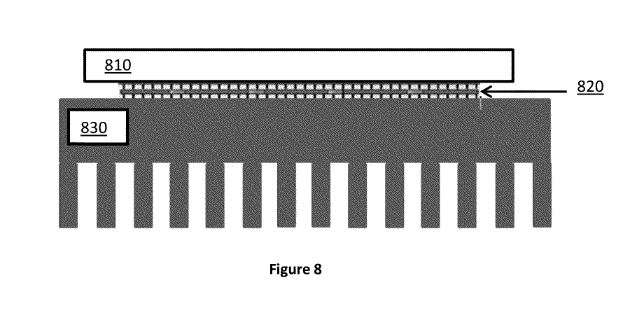

FIG. 8 illustrates one embodiment of an apparatus which includes a device 810, a heat sink 830 and a thermal interface material 820. The thermal interface material 820, includes vertically aligned carbon nanotubes disposed on both side of a metal substrate which includes cavities. The thermal interface material 820 is in conductive contact with device 810 and heat sink 830 and conducts heat from device 810 to heat sink 830.

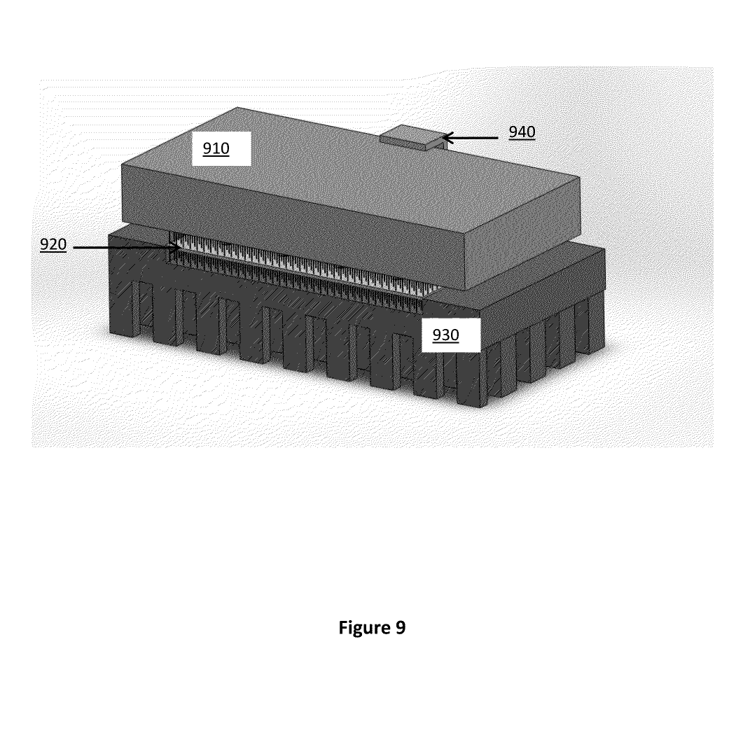

FIG. 9 illustrates another embodiment of an apparatus which includes a device 910, a heat sink 930 a thermal interface material 920 and a clamp 940 which secures. The thermal interface material 920, includes vertically aligned carbon nanotubes disposed on both side of a metal substrate which includes cavities. The carbon nanotube density is lower at the edges of the cavities. The thermal interface material 920 is in conductive contact with device 910 and heat sink 930 and conducts heat from device 910 to heat sink 930.

In some of the above embodiments, the device is a light emitting diode, a microelectronic chip, a power chip, a battery or a battery pack.

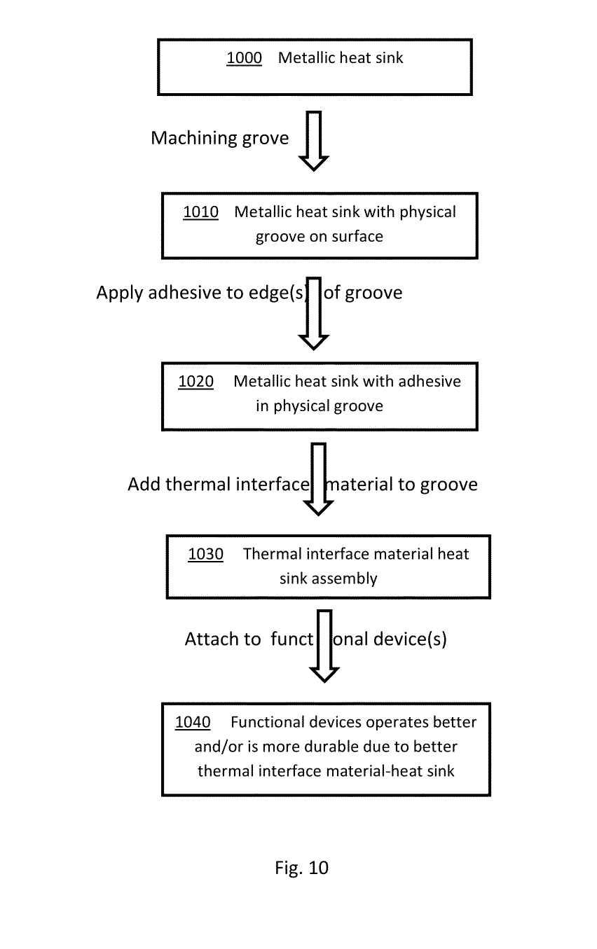

FIG. 10 illustrates making an embodiment of an apparatus including a thermal interface material incorporating carbon nanotubes attached in a permanent fashion to a heat sink. A depression is fabricated on the surface of a heat sink 1000 to provide a heat sink with a depression 1010. In some embodiments, an adhesive is added at one or more of the edges of the depression on the heat sink to provide 1020 where immobilize thermal interface material in the heat sink depression. In other embodiments, an adhesive is added at one or more of the corners of the depression on the heat sink to provide 1020 immobilize thermal interface material in the heat sink depression. Next, at 1030 a thermal interface material is immobilized in the depression of the heat sink by the adhesive. The apparatus is then attached to a functional device at 1040 where superior heat transfer to the heat sink provides better device operation and/or durability.

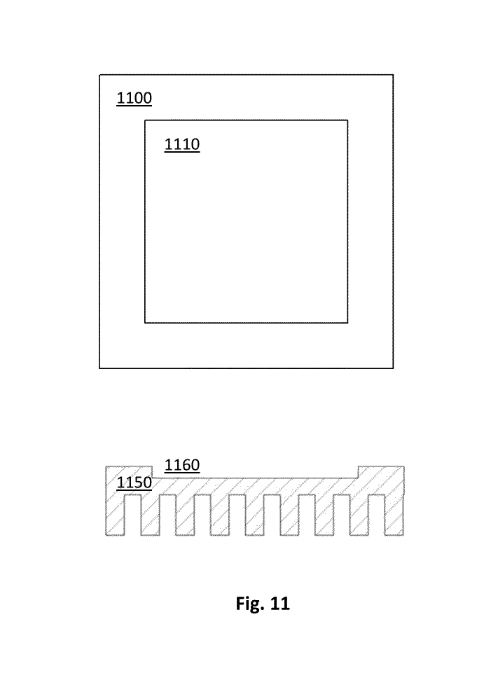

FIG. 11 illustrates a heat sink which includes a depression 1110 and 1150 from a top-down view 1100 and a cross-sectioned view 1160. The depression may have any geometric shape, depth or size including those provided above. The size, shape and depth of the depression in the heat sink may be designed to seamlessly immobilize thermal interface material. The depression may have a size with a length equals to the length of one or more of the sides of the heat sink. The depression may have less than 4 sides onto which the thermal interface material is physically aligned to one or more sides of the depression.

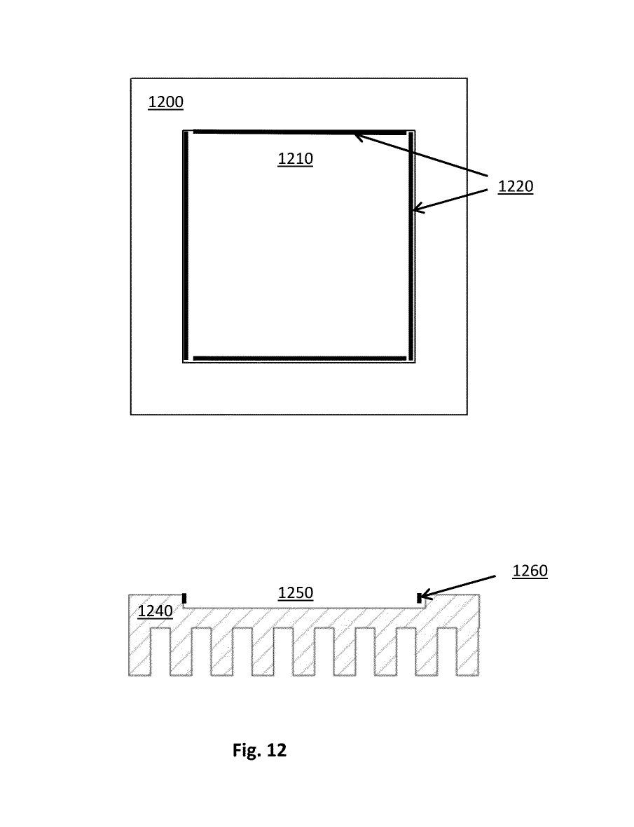

FIG. 12 illustrates embodiments where an adhesive is applied to the depression in the heat sink to immobilize thermal interface material. In some embodiments, the thermal interface material is permanently immobilized. In other embodiments, adhesive 1220 is applied to one or more of the edges of the depression 1210 on the heat sink surface 1200. In still other embodiments, an adhesive 1260 is applied to one or more of the corners of the depression 1250 on the heat sink surface 1240. In still other embodiments, an adhesive is applied to a combination of one or more of the edges and corners of the depression structure the heat sink surface.

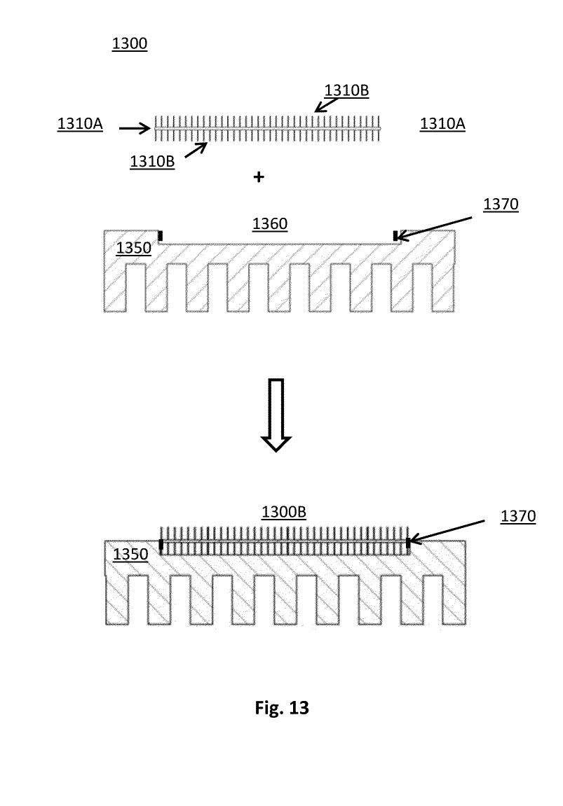

FIG. 13 illustrates an embodiment 1300 where thermal interface material 1310 is attached to edges of the depression 1360 in the heat sink 1350 with an adhesive 1370. Here, the thickness of the thermal interface material, including the metal substrate 1310A and two vertically aligned carbon nanotube arrays 1310B disposed on two opposing sides the metal substrate are attached, is greater than the depth of the depression 1360 on the heat sink. As illustrated in embodiment 1300B, the vertically aligned carbon nanotube array of one side of the thermal interface material is in conductive contact with heat sink 1350 and the vertically aligned carbon nanotube array on the other side of the thermal interface material protrudes from the surface of the heat sink. In some embodiments, the vertically aligned carbon nanotube array protrudes from the surface of the heat sink by greater than about 10 μm. In other embodiments, the vertically aligned carbon nanotube array protrudes from the surface of the heat sink by less than about 10 μm.

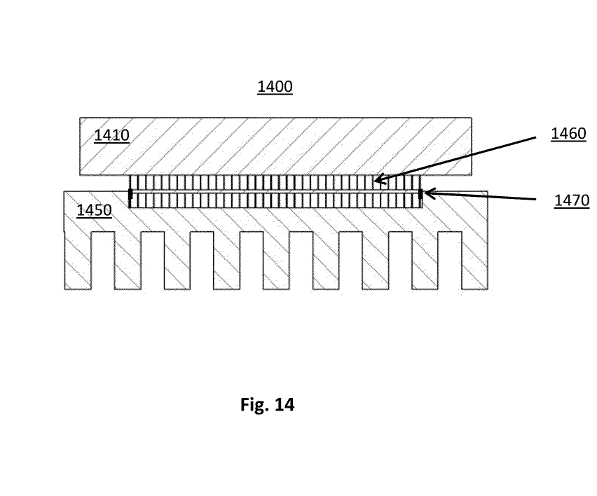

FIG. 14 illustrates an embodiment 1400, where heat is transferred from functional device 1410 to heat sink 1450. Here, one of the VACNT arrays on one side of the thermal interface material 1460 protrudes from the surface of the heat sink and is in conductive contact with functional device 1410. The tips of the carbon nanotubes make contact with and transfer heat from the device 1410 to the heat sink. In some embodiments, the functional device a desktop, laptop, or tablet computer, and light emitting diode device, a power electronic device, a battery or a battery system.

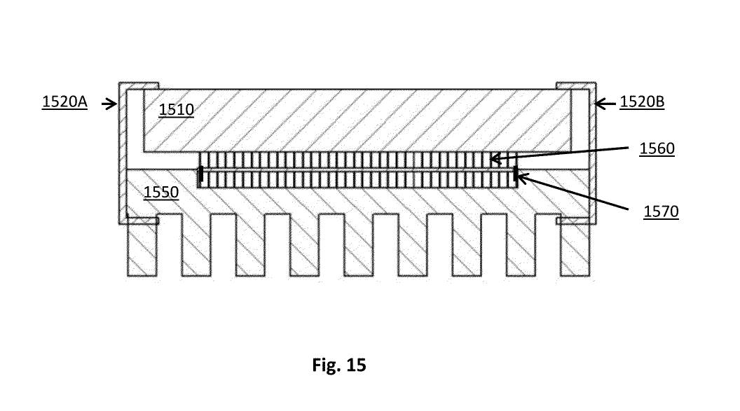

FIG. 15 illustrates heat transfer from a functional device 1510 to an apparatus (i.e., 1560 attached to 1550) described herein. In some embodiments, the apparatus (i.e., 1560 attached to 1550) is integrated with functional device 1510 and held together in place with a clamp 1520A or a set of clamps 1520A and 1520B. In some embodiments, the apparatus (i.e., 1560 attached to 1550) is used to transfer heat from a functional device 1510 such as, for example, microelectronic devices (e.g., desktop, laptop, or tablet computer), a light emitting diode device, a battery or a battery system.

Finally, it should be noted that there are alternative ways of implementing the present invention. Accordingly, the present embodiments are to be considered as illustrative and not restrictive, and the invention is not to be limited to the details given herein, but may be modified within the scope and equivalents of the appended claims.

All publications and patents cited herein are incorporated by reference in their entirety.

What is claimed is:

1. An apparatus comprising a thermal interface material including carbon nanotubes attached to a depression on a heat sink, wherein the thickness of the thermal interface material is greater than the depth of the depression on the heat sink.

2. The apparatus of claim 1 wherein the thermal interface material includes substances comprising carbon nanotubes disposed on at least one side of a metal substrate including one or more cavities.

3. The apparatus of claim 1, wherein the thermal interface material includes substances comprising carbon nanotubes disposed on two opposing sides of a metal substrate which includes one or more cavities.

4. The apparatus of claim 1, wherein the thermal interface material is attached to the heat sink with an adhesive.

5. The apparatus of claim 4, wherein the adhesive is comprised of a thermal paste, thermal grease, epoxy, silver epoxy or combinations thereof.

6. The apparatus of claim 4, wherein the adhesive is applied to an edge of the depression on the heat sink.

7. The apparatus of claim 1, wherein the heat sink is comprised of aluminum or aluminum alloy.

8. The apparatus of claim 1, wherein the heat sink is comprised of copper or copper alloy.

9. The apparatus of claim 1, wherein the depression has a depth between about 500 μm and about 2000 μm.

10. The apparatus of claim 1, wherein the depression has a depth between about 50 μm and about 500 μm.

11. The apparatus of claim 1, further comprising attaching functional device(s) to the thermal interface material.

12. The apparatus of claim 11, wherein the device is a microelectronic device, a computer, a LED device, a power electronic device, a battery, a battery system or a space system.

13. A method of making the apparatus of claim 1 comprising:
attaching the thermal interface material to the heat sink depression;
attaching a device to the thermal interface material.
